(19) United States
(12) Patent Application Publication
(10) Pub. No.: US 2013/0104949 A1
(43) Pub. Date: May 2, 2013

(54) THERMOELECTRIC CONVERTER DEVICES

(71) Applicants: Hans Walitzki, Portland, OR (US); Rodney T. Cox, North Plains, OR (US)

(72) Inventors: Hans Walitzki, Portland, OR (US); Rodney T. Cox, North Plains, OR (US)

(21) Appl. No.: 13/662,507

(22) Filed: Oct. 28, 2012

Related U.S. Application Data
(60) Provisional application No. 61/553,063, filed on Oct. 28, 2011.

(51) Int. Cl. H01L 35/32

(52) U.S. Cl. 136/200

(57) ABSTRACT

An improved thermoelectric converter device capable of effective and efficient high temperature operation is provided. The device includes at least a pair of spaced electrodes including substrates made from polished single crystal sapphire and active low and high temperature heat transfer regions contiguous with the electrodes and formed from materials selected to enhance heat transfer, particularly at high temperatures. The device is capable of more efficient operation and increased operating efficiencies over a wider range of temperatures than has heretofore been possible.

### PRIORITY CLAIM

This application claims priority from U.S. Provisional Patent Application No. 61/553,063, filed 28 Oct. 2011, the disclosure of which is fully incorporated herein.

### TECHNICAL FIELD

The present invention relates generally to thermionic and thermotunneling thermoelectric conversion devices and specifically to improvements in such devices to make them useful for sustained high temperature operation and for effective heat transfer.

### BACKGROUND OF THE INVENTION

Devices which, on a micro scale or nano scale level, use a thermal gradient to create electric power or that use electric power or energy to pump heat have been described in the art, although none appear to be commercially available at the present time. These devices, which typically do not have moving parts, generally operate on the basis of electron transport between electrodes at different temperatures. To the best of our knowledge, such devices are working in deep space probes, for example atop plutonium piles, with an efficiency that is not greater than about 10%. Even after long development programs, commonly available and relatively inexpensive thermoelectric devices have efficiencies that are clearly less than 10% of Carnot.

Examples of this art include, for example, European Patent Publication No. EP 1009958B1 and U.S. Pat. No. 6,720,704 to Tavkhelidze et al, both of which are owned by the assignee of the present invention. The European Patent Publication relates to an improved vacuum diode heat pump with low work function electrodes using electrons as the working fluid that provides cost-effective cooling. Tavkhelidze et al describe thermionic vacuum diode devices in which the separation of electrodes is set and controlled using piezo-electric, electrostrictive or magnetostrictive actuators, which avoids problems associated with electrode spacing changing or distorting as a result of heat stress. In addition it allows the operation of these devices at electrode separations which permit quantum electron tunneling between them. A polished metal plate, preferably tungsten, forms one of the electrodes. Tavkhelidze et al also disclose, in commonly owned U.S. Pat. No. 6,417,060, a method for manufacturing a pair of electrodes, preferably including a polished tungsten monocrystal, useful in thermionic converters and generators, thermotunnel converters, and vacuum diode heat pumps with a pair of electrodes separated by a defined gap that is less than 50 nanometers and preferably less than 5 nanometers. The disclosures of the aforementioned patents and patent publication are incorporated herein by reference.

Silicon has been used as the substrate of choice in thermionic/thermotunneling devices, but has been found to suffer from disadvantages during operation at high temperatures, particularly at temperatures above 800° to 900° K. The tendency of silicon to flow at temperatures above this range limits its effective use. Silicon would eventually fill in the gap between electrodes, thereby limiting the operational lifetime of devices with close-spaced electrodes.

Sapphire, in particular artificially produced sapphire, has been used as a substrate in semiconductor and some other electronic applications, both alone and in combination with silicon. Sapphire is recognized to provide good electrical insulation and heat conduction in some integrated circuits. It also can reduce the cost of blue light-emitting diodes by replacing the significantly more costly germanium as a substrate. U.S. Pat. No. 6,232,623 to Morita and U.S. Patent Application Publication Nos. US2004/0109486 to Kinoshita et al and US2008/0246054 to Suzuki, for example, describe the use a sapphire substrates in semiconductor devices. Kinoshita et al discloses a monocrystal sapphire substrate formed by cleaving artificially produced sapphire in a desired plane to produce a laser diode. Suzuki also discloses a light-emitting device formed initially on a sapphire base that includes nitride semiconductor layers in which the sapphire layer is ultimately removed to form the finished product. Morita further discloses a light-emitting diode and semiconductor laser with a c-plane sapphire substrate provided with a plurality of recesses formed on a major surface of the sapphire crystal to improve the coupling of layers of nitride III-V compounds to the sapphire substrate. Neither the foregoing patent nor the cited publications suggests that the sapphire-containing structures described therein could by themselves function at or could be modified to function at the temperatures required to improve the transfer of heat or the generation of electric power in a thermionic/thermotunneling thermoelectric converter or like device.

A need exists, therefore, for an improved thermoelectric converter device that incorporates the heat transfer efficiency and high temperature benefits resulting from employing a sapphire substrate in such a device. A need also exists for devices of this type that are capable of achieving efficiencies greater than 10% of Carnot efficiency, as well as efficiencies of operation over a wide range of temperatures.

### SUMMARY OF THE INVENTION

It is a primary object of the present invention, therefore, to provide an improved thermoelectric converter device that incorporates the heat transfer efficiency and high temperature benefits that result from employing a sapphire substrate in such a device.

It is another object of the present invention to provide an improved thermoelectric converter device that incorporates a polished sapphire single crystal substrate in electrodes forming the device.

It is an additional object of the present invention to provide an improved thermoelectric converter device capable of more efficient operation than has heretofore been possible.

It is a further object of the present invention to provide an improved thermoelectric converter device capable of increased efficiency of operation over a wide range of temperatures.

It is yet another object of the present invention to provide an improved thermoelectric converter device capable of efficient sustained operation at higher temperatures than has heretofore been possible.

It is yet a further object of the present invention to provide an improved thermoelectric converter device capable of achieving greater than 10% of Carnot efficiency.

It is a still further object of the present invention to provide an improved thermoelectric converter device that combines a low temperature active area with a high temperature active area, wherein the materials and the geometries of the materials that form the active areas are selected to promote effective heat transfer.

It is yet an additional object of the present invention to provide an improved thermoelectric converter device that includes active heat transfer areas formed of two different materials, each with a different coefficient of expansion, so that the expansion of the active area material on a cold side of the device matches the expansion of the active area material on a hot side of the device as the device is cycled from ambient to operating temperature.

In accordance with the aforesaid objects, an improved thermoelectric converter device is provided. The present thermoelectric converter includes at least a pair of electrodes separated by spacers disposed between the electrodes so that there is a larger gap between the electrodes than has heretofore been possible. The electrodes include a substrate formed from a material, preferably polished single crystal sapphire, which is designed to enable the device to operate with improved efficiency as well as efficiently at a wide range of temperatures, and particularly at high operating temperatures. Surfaces of the electrodes are preferably patterned, optionally using Avto metals patterning. The thermoelectric converter device of the present invention further includes high temperature and low temperature active areas, each active area being contiguous with an electrode, wherein the active areas are formed from materials selected to enhance heat transfer.

Other objects and advantages will be apparent from the following description, drawings, and claims.

### BRIEF DESCRIPTION OF THE DRAWINGS

FIG. 1 is a diagrammatic representation of an electrode with a sapphire substrate for an improved thermoelectric converter device in accordance with the present invention; and

FIG. 2 shows a cross sectional view of an improved thermoelectric converter device including a pair of spaced electrodes and a sapphire substrate according to the present invention, showing active areas and the direction of heat flow through the thermoelectric converter device.

### DESCRIPTION OF THE INVENTION

Thermionic and thermotunneling thermoelectric converter devices may include at least a pair of spaced electrodes maintained at a desired effective distance from each other by spacers without requiring the presence of active elements. Surfaces of such electrodes may or may not include Avto metals patterning. Devices of this type and a method for making such devices are described in commonly owned U.S. Patent Publication No. US2009/0223548 by Walitzki et al, the disclosure of which is incorporated herein by reference. The silicon-based devices shown and described in this publication provide useful and effective thermionic and thermotunneling thermoelectric converter devices. Replacing the silicon substrates employed in these devices with single crystal polished sapphire substrates and active areas formed of materials selected for effective heat transfer produces improved thermoelectric converter devices that are particularly useful in high temperature applications where silicon substrates present challenges.

The improved thermoelectric converter devices described herein can be more specifically described with reference to the following terms:

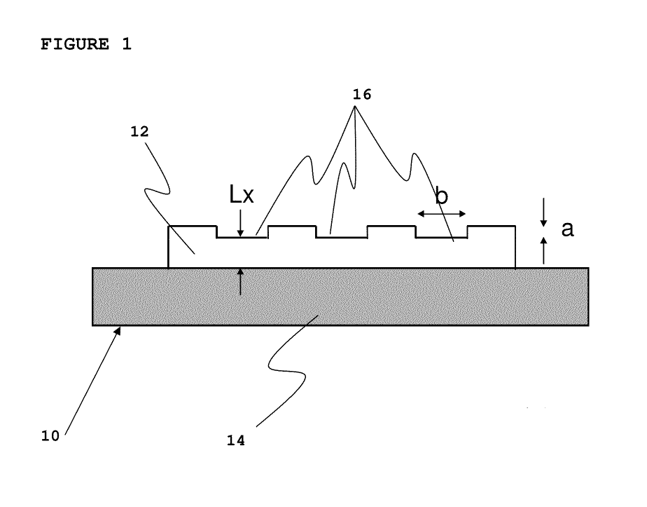

“Thermionic or thermotunneling converter” is hereby defined as either a device that uses a thermal gradient to create electrical power or a device that uses electrical power or energy to pump heat, thereby creating, maintaining, or degrading a thermal gradient. This may be accomplished using thermionics, thermotunneling, the Avto effect, or other methods. The terms “thermoelectric” and “thermoelectric converter” are to be understood to include both “thermotunneling” and “thermionic” applications and devices. In the following disclosure “thermotunneling” is used by way of an example only. The terms “Avto metal” and “Avto effect” are to be understood to describe a metal film having a modified shape that alters the electronic energy levels inside an electrode modified accordingly, leading to a decrease in electron work function as described and shown in connection with FIG. 1 below. Instances in which forthcoming descriptions refer to a cooling device are by way of an example only and should not serve to limit the present invention. Further, as used herein, the term “electrode” is intended to include either or both an anode or a cathode, as appropriate.

The owner of the present invention presently develops thermoelectric converter devices under the names COOL CHIPS™, POWER CHIPS™, and AVTO QUANTUM TRANSISTORS™, as well as Avto Effect coatings and other related products. POWER CHIPS™ refers to devices that use a thermal gradient to create electric power, and COOL CHIPS™ refers to devices that use electric power or energy to pump heat. AVTO QUANTUM TRANSISTOR™ refers to transistors that use the Avto effect. References made to these devices herein are not intended to be limiting.

The sapphire substrates preferred for use in the thermoelectric converter devices of the present invention are polished single crystal, preferably artificial, sapphire structures capable of effective heat transfer at high temperatures over a sustained period of time. These sapphire substrates enable thermoelectric converter devices to work efficiently to transfer heat at temperatures ranging from ambient temperatures to temperatures exceeding about 800° to 900° K for power production, which is a much wider temperature range of efficient operation than presently is possible. Sapphire substrates may also allow cooling at higher temperatures, including temperatures exceeding 800° to 900° K, and wider temperature ranges than are possible at present. The thermoelectric converter devices of the present invention additionally are also capable of operation at increased efficiencies compared to available devices, achieving greater than 10% of Carnot efficiency.

As discussed above, the silicon substrates previously employed in thermoelectric converter and like devices do not work at these temperatures. At temperatures above about 700° K, silicon does not maintain the integrity required to support thermoelectric conversion. The sapphire substrates of the present invention overcome this limitation.

Referring to the drawings, FIG. 1 illustrates an Avto metal structure 10, in particular the shape and dimensions of a modified electrode having a thin metal film 12 on a substrate 14. The substrate 14 is formed from a polished sapphire single crystal. Each indent 16 has a width b and a depth a relative to a height of metal film 12. The height or thickness of the metal film 12 is Lx+a. Film 12 is preferably a metal with a surface that is as planar as possible, since surface roughness leads to the scattering of de Broglie waves. Metal film 12 is given a sharply defined geometric pattern, such as the indents 16 shown in FIG. 1. The indents 16 each have a dimension that creates a de Broglie wave interference pattern that leads to a decrease in electron work function. This configuration facilitates the emissions of electrons from a surface of the metal film 12 and promotes the transfer of elementary particles across a potential barrier (not shown). The surface configuration of the modified electrode may resemble a corrugated pattern of squared-off, “u”-shaped ridges and/or valleys. Alternatively, the pattern may be a regular pattern of rectangular “plateaus” or “holes,” where the pattern resembles a checkerboard. The walls of each indent 16 should be substantially perpendicular to one another, and the edges of each indent should be substantially sharp. Methods of forming patterned electrode surfaces that produce the Avto effect are described and shown in commonly owned U.S. Pat. No. 6,117,344 to Cox et al, the disclosure of which is incorporated herein by reference.

The surface configuration comprises a substantially planar slab of a material, such as, for example the metal described above, having on one surface at least one and preferably more indents 16. While the dimensions of the indents required to produce the Avto effect can vary, a depth in the range of approximately 5 to 20 times a roughness of the surface and a width in the range of approximately 5 to 15 times the depth is preferred. As previously indicated, the walls of the indents are preferably substantially perpendicular to one another, and the edges of the indents are preferably substantially sharp. A sapphire substrate 14 gives the structure of an Avto metal device a hardness and toughness not possible with a silicon substrate. Additionally, the preferred artificial sapphire material has a high melting temperature, high mechanical strength and high thermal conductivity.

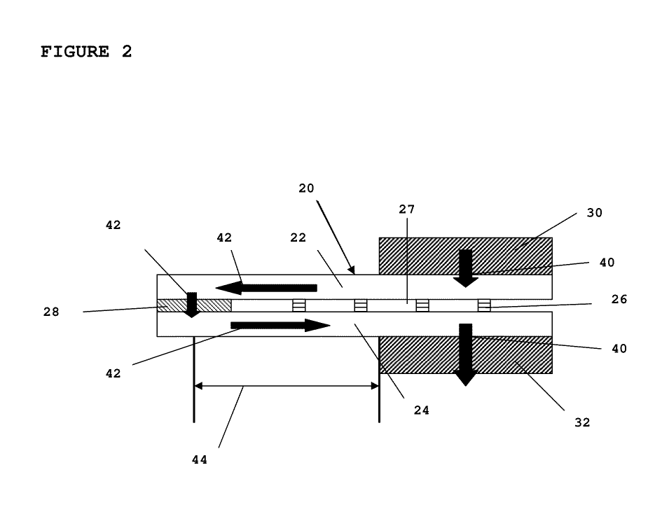

FIG. 2 shows, in cross-section, a thermoelectric converter 20 that includes a pair of electrodes 22 and 24, preferably an anode and a cathode, with a plurality of spacers 26 that maintain the electrodes at a desired separation distance or gap 27. One of the major advantages and improvements achieved by the present invention is the production of efficient devices with much greater spacing between cathode and anode than has previously been possible. This greater spacing between electrodes achieves the same efficiency levels as in the past because of the higher thermal toleration possible. Separation between electrodes can exceed the 50 nanometer gap distance disclosed in commonly owned U.S. Pat. No. 6,417,060 referred to above without sacrificing efficiency.

Each electrode 22 and 24 may have the structure shown in FIG. 1, although other structures could also be provided to produce an improved thermotunneling or thermoelectric converter device with a polished sapphire substrate in accordance with the present invention. Each of the electrodes 22 and 24 is formed on a polished single crystal sapphire substrate, with a plurality of indents as described in connection with FIG. 1 or another convenient configuration, so that the electrodes of the thermoelectric converter 20 have identical dimensions. A bond pad 28 may be positioned at an end of and between the electrodes 22 and 24 to hold them in place. An active area 30 is contiguous to and in contact with the electrode 22 and in heat transfer contact with a device to be cooled (not shown), whereas an active area 32 contiguous to and in contact with the electrode 24 is in thermal contact with a heat sink (not shown). The active areas may or may not have Avto metals patterning.

Arrows 40 indicate the direction in which heat flows through the thermoelectric converter active areas 30 and 32. Arrows 42 indicate the path along which the heat will travel through the electrodes 22 and 24. Active areas 30 and 32 are not in close proximity to the bond pad 28 holding the electrodes 22 and 24 in place, but are separated by a distance represented by the arrow 44. As a result, any thermal leakage through the bond pad 28 will be minimized. In addition, edge thermal losses may be reduced when the effective area of the thermotunneling converter device 20 is enlarged in comparison to an edge zone or the length of the thermal path is increased by methods well known in the art.

Active area 30, which is the low temperature side of the thermoelectric converter device of the present invention, is preferably formed of an organic heat transfer material of the type that can be extruded or cast and then polished. An organic heat transfer material that can be formed directly on the electrode 22 so that an optimum smoothness is produced without polishing is also contemplated to be within the scope of the present invention. Other heat transfer materials useful in a low temperature area, such as, for example, polished metallic heat transfer materials and cast, sintered, or grown and polished ceramic heat transfer materials, could also be used to form the active area 30.

Active area 32, which is the high temperature side of the thermoelectric converter device of the present invention, could be formed from any one of a variety of materials suitable for heat transfer in a high temperature area. These materials include, for example without limitation, corundum, silicon nitride, gallium nitride, silicon carbide, quartz, and suitable heat transfer ceramic materials, in single crystal and other forms.

It is additionally contemplated to be within the scope of the present invention to form the low temperature active area 30 and the high temperature active area 32 from materials that are selected to have different coefficients of expansion. The combination of materials is preferably selected so that the expansion on the low temperature side matches the expansion on the high temperature side. This arrangement may be particularly beneficial in a POWER CHIP™ device during cycling from ambient to operating temperature to produce electrical energy or electric power.

For some applications, it may be useful to coat the sapphire substrate with silicon. The performance of the thermoelectric converter devices described herein may be further improved in these applications.

Devices that include a plurality of improved thermoelectric converters 20 with sapphire substrates may be produced as described in the commonly owned patents and publications referred to above.

While the present invention has been described with respect to a limited number of embodiments, those skilled in the art will appreciate numerous modifications and variations therefrom. It is intended that the appended claims cover all such modifications and variations as fall within the true spirit and scope of this present invention.

### INDUSTRIAL APPLICABILITY

The present invention will find its primary applicability in providing improved thermionic/thermotunneling devices for thermoelectric conversion capable of sustaining operation at significantly higher and wider ranges of temperatures and generating more efficient operating efficiencies than were previously possible.

1. A thermoelectric converter device comprising at least a pair of spaced electrode means configured to transfer heat, wherein said pair of electrode means is separated by a gap, and each said electrode means comprises substrate means, wherein said gap has a distance selected and said substrate means is formed of a material selected to enable said device to transfer heat with improved efficiency over a range of temperatures.

2. The thermoelectric converter device of claim 1, wherein the selected material of said substrate means comprises polished single crystal sapphire.

3. The thermoelectric converter device of claim 1 wherein the selected material of said substrate means transfers heat efficiently at temperatures ranging from ambient temperatures to temperatures of at least about 800° to 900° K.

4. The thermoelectric converter device of claim 1 wherein said selected material is polished single crystal sapphire and said high temperature operation occurs at temperatures in the range of from ambient temperatures to temperatures of at least about 800° to 900° K.

5. The thermoelectric converter device of claim 1 wherein each one of said pair of spaced electrode means is contiguous to active area means for actively transferring heat through said device.

6. The thermoelectric converter device of claim 5 wherein a first active area means is contiguous to a first electrode of said pair of electrode means and is in heat transfer contact with a device to be cooled and a second active area means is contiguous to a second electrode of said pair of electrode means and is in heat transfer contact with a heat sink.

7. The thermoelectric converter device of claim 6, wherein said first active area means comprises a material selected from the group consisting of polished metallic heat transfer materials, cast, sintered, or grown and polished ceramic heat transfer materials, and extruded or cast and polished organic heat transfer materials.

8. The thermoelectric converter device of claim 6, wherein said second active area means comprises a material selected from the group consisting of corundum, silicon nitride, gallium nitride, silicon carbide, quartz, and heat transfer ceramics.

9. The thermoelectric converter device of claim 6, wherein said first active area means comprises a material having a first coefficient of expansion and said second active area means comprises a material having a second coefficient of expansion, and said materials are selected so that said first coefficient of expansion matches said second coefficient of expansion as the thermoelectric converter device is cycled from an ambient temperature to an operating temperature.

10. A thermoelectric converter device for transferring heat efficiently during high temperature operation, said device comprising at least a pair of spaced electrodes comprising at least a first electrode and a second electrode configured to transfer heat and separated by a gap from said first electrode, wherein each of said first electrode and said second electrode comprises substrate means comprising polished single crystal sapphire configured to transfer heat efficiently at temperatures ranging from ambient temperatures to temperatures of at least about 800° to 900° K, and each of said first and second electrodes includes active area means contiguous with said electrode and formed of materials selected to transfer heat effectively.

11. The thermoelectric converter device of claim 10, wherein the active area means of said first electrode is in heat transfer contact with a device to be cooled and the active area means of said second electrode is in heat transfer contact with a heat sink.

12. The thermoelectric converter device of claim 11, wherein the active area means of said first electrode is comprises a material selected from the group comprising polished metallic heat transfer materials, cast, sintered, or grown and polished ceramic heat transfer materials, and extruded or cast and polished organic heat transfer materials; and the active area means of said second electrode comprises a material selected from the group comprising corundum, silicon nitride, gallium nitride, silicon carbide, quartz, and heat transfer ceramics.

13. The thermoelectric converter device of claim 6, wherein the selected material of said substrate means comprises polished single crystal sapphire modified with a thin metal film, wherein a surface of said thin metal film not in contact with said single crystal sapphire has a sharply defined geometric pattern comprising a plurality of indents with dimensions selected to create a de Broglie wave interference pattern that leads to a decrease in electron work function.

14. The thermoelectric converter device of claim 13, wherein the configuration and heat transfer arrangement of said first and second electrodes and said first and second active area means achieves a device operating efficiency of at least 10% of Carnot.

15. The thermoelectric converter device of claim 10, wherein said substrate means of each said first electrode and said second electrode comprises polished single crystal sapphire modified by the application of a thin metal film, wherein a surface of said thin metal film not in contact with said single crystal sapphire has a sharply defined geometric pattern comprising a plurality of indents with dimensions selected to create a de Broglie wave interference pattern that leads to a decrease in electron work function.

16. The thermoelectric converter device of claim 15, wherein the configuration and arrangement of components of said device achieves a device operating efficiency of at least 10% of Carnot.
